(19) United States
(12) Patent Application Publication
(10) Pub. No.: US 2022/0077250 A1
(43) Pub. Date: Mar. 10, 2022

(54) DISPLAY PANEL AND MANUFACTURING METHOD OF SAME

(71) Applicant: SHENZHEN CHINA STAR OPTOELCTRONICS SEMICONDUCTOR DISPLAY TECHNOLOGY CO., LTD., Shenzhen, Guangdong (CN)

(72) Inventor: Jia TANG, Shenzhen, Guangdong (CN)

(73) Assignee: SHENZHEN CHINA STAR OPTOELECTRONICS SEMICONDUCTOR DISPLAY TECHNOLOGY CO., LTD., Shenzhen, Guangdong (CN)

(21) Appl. No.: 16/972,027

(22) PCT Filed: Nov. 10, 2020
(86) PCT No.: PCT/CN2020/127815

§ 371 Date: Dec. 4, 2020

(30) Foreign Application Priority Data
Sep. 4, 2020 (CN) 202010920984.0

(51) Int. Cl. H01L 27/32; H01L 51/52; H01L 51/56

(52) U.S. Cl. CPC H01L 27/3246; H01L 2227/323; H01L 51/56; H01L 51/5218

(57) ABSTRACT

A display panel and a manufacturing method of the same are provided. The display panel includes an array substrate, a plurality of reflective electrodes located on the array substrate and distributed in an array, isolation units arranged between any two adjacent reflective electrodes, an anode layer comprising first anodes located on each of the reflective electrodes and second anodes located on a side of each of the isolation units away from the array substrate, and a light-emitting functional layer located on the first anode. Each of the first anodes is separated from the adjacent second anodes by the isolation unit.

### FIELD OF INVENTION

The present application relates to the field of display technologies, in particular to a display panel and a manufacturing method of the same.

### BACKGROUND OF INVENTION

Luminous efficiency and accurate control of luminous wavelength of top-emitting OLED (organic light emitting diode) devices have always been an issue in the development of OLED devices. One of the main factors that affect the luminous efficiency of OLED devices and the accurate control of luminous wavelength is: control of a cavity length of the OLED device (cavity length generally refers to a direct distance between a reflective electrode at a bottom of an anode and a cathode). Due to influence of a microcavity effect, the luminous efficiency and wavelength position of each sub-pixel are not optimized, especially position accuracy of a light output wavelength is greatly affected, resulting in low life and efficiency of the OLED device.

An anode structure in a current top-emitting OLED device is composed of a reflective electrode and an anode (material is ITO) covering the reflective electrode. The reflective electrode and anode are made by a mask. The anode is generally a low-thickness ITO film (150 A thick). It is difficult to adjust the cavity length depending on a thickness of the OLED organic material. Therefore, a thickness of the anode on the anode structure plays an important role in an adjustment of the cavity length. Through simulation of the best efficiency of the device, it can be known that the best efficiency of the device is when the thickness of the anode is about 800 A.

There are currently two main options for adjusting the cavity length: The first solution is to thicken the anode (ITO material) to 800 A. The second solution is to add a transparent spacer between the anode (ITO material) and the reflective electrode. The material of the spacer includes silicon oxide or other transparent organic materials. However, for the first solution, the anode is formed through an etching process. Thickening of the anode made of ITO material (for example, thicker than 400 A) is easy to crystallize, and it is easy to cause etching residue. Especially when the anode material is deposited on the metal reflective electrode (the material is generally Ag or Al), the crystallization is more serious, resulting in the failure of normal etching. For the second solution, it is necessary to introduce an exposure and development process or a chemical vapor deposition (CVD) and etching process for patterning of a gasket. The process is complicated and is not conducive to mass production.

### SUMMARY OF INVENTION

The present application provides a display panel and a manufacturing method of the same. By arranging an isolation unit between two adjacent reflective electrodes, two adjacent first anodes can be naturally disconnected. A cavity length of the device can be adjusted by a thickness of the first anode, which solves an issue that an anode layer with a larger thickness is difficult to etch. At the same time, an issue of complicated process caused by setting a spacer between the anode layer and the reflective electrode to adjust the cavity length of the device is solved.

In a first aspect, the present application provides a display panel, comprising: an array substrate; a plurality of reflective electrodes located on the array substrate and distributed in an array; a plurality of isolation units, wherein one isolation unit is arranged between any two adjacent reflective electrodes; an anode layer comprising first anodes located on each of the reflective electrodes and second anodes located on a side of each of the isolation units away from the array substrate; a light-emitting functional layer located on the first anode; wherein each of the first anodes is separated from the adjacent second anodes by the isolation unit.

In the display panel according to the present application, a width of the isolation unit gradually increases in a direction of the array substrate toward the second anode, and an orthographic projection of an upper surface of the isolation unit on the array substrate completely covers an orthographic projection of a lower surface of the isolation unit on the array substrate.

In the display panel according to the present application, a shape of a cross section of the isolation unit in a direction perpendicular to the array substrate is an inverted trapezoid.

In the display panel according to the present application, the cross section comprises two oppositely arranged oblique sides; an angle between each oblique side and an upper surface of the array substrate is greater than or equal to 45° and less than or equal to 60°.

In the display panel according to the present application, a thickness of the isolation unit is greater than a sum of thicknesses of the reflective electrode and the first anode.

In the display panel according to the present application, the thickness of the first anode is greater than or equal to 800 A; the thickness of the isolation unit is greater than or equal to 1 um.

In the display panel according to the present application, the display panel further comprises a pixel definition layer covering an upper surface and a side surface of each of the second anodes.

In the display panel according to the present application, the pixel definition layer further partially covers the first anode and the reflective electrode to form a pixel opening, and the light-emitting functional layer is located in the pixel opening.

In the display panel according to the present application, material of the anode layer comprises indium tin oxide.

In the display panel according to the present application, the first anode and the second anode have same material and a same thickness.

In the display panel according to the present application, the array substrate comprises a base substrate, a buffer layer disposed on the base substrate, and a plurality of thin film transistors disposed on the buffer layer and connected to the plurality of reflective electrodes in a one-to-one correspondence.

In a second aspect, the present application further provides a manufacturing method of a display panel comprising following steps: providing an array substrate; forming a plurality of reflective electrodes distributed in an array on the array substrate; forming isolation units between any two adjacent reflective electrodes; covering an anode layer on the array substrate on which the reflective electrodes and the isolation unit are formed, to form first anodes located on each of the reflective electrodes and second anodes located on a side of each of the isolation units away from the array substrate; wherein the first anodes and the second anodes are separated by the isolation units; and forming a light-emitting functional layer on the first anode.

In manufacturing method of the display panel according to the present application, a width of the isolation unit gradually increases in a direction of the array substrate toward the second anode, and an orthographic projection of an upper surface of the isolation unit on the array substrate completely covers an orthographic projection of a lower surface of the isolation unit on the array substrate.

In manufacturing method of the display panel according to the present application, a shape of a cross section of the isolation unit in a direction perpendicular to the array substrate is an inverted trapezoid.

In manufacturing method of the display panel according to the present application, the cross section comprises two oppositely arranged oblique sides; an angle between each oblique side and an upper surface of the array substrate is greater than or equal to 45° and less than or equal to 60°.

In manufacturing method of the display panel according to the present application, a thickness of the isolation unit is greater than a sum of thicknesses of the reflective electrode and the first anode.

In manufacturing method of the display panel according to the present application, the thickness of the first anode is greater than or equal to 800 A; the thickness of the isolation unit is greater than or equal to 1 um.

In manufacturing method of the display panel according to the present application, forming the light-emitting functional layer on the first anode comprises following steps: forming a pixel definition layer covering an upper surface and a side surface of each of the second anodes, wherein the pixel definition layer further partially covers the first anode and the reflective electrode to form a pixel opening; forming the light-emitting functional layer on the first anode located in the pixel opening.

In manufacturing method of the display panel according to the present application, material of the anode layer comprises indium tin oxide.

In manufacturing method of the display panel according to the present application, the first anode and the second anode have same material and a same thickness.

### Beneficial Effect

In the display panel and the manufacturing method of the same provided in the present application, an isolation unit is arranged between any two adjacent reflective electrodes. This makes it possible to form the first anode on the reflective electrode and the second anode on the isolation unit when the anode layer is formed on the array substrate on which the isolation unit and the reflective electrode are formed. The first anode and the second anode are naturally separated by the isolation unit. Therefore, any two adjacent first anodes are naturally separated by the isolation unit. Therefore, in the present application, the first anode with a larger thickness and spaced apart can be directly formed without using an etching process when making the anode layer. This is beneficial to adjust a cavity length of the OLED device in the display panel through the thickness of the first anode, so as to improve luminous efficiency, precision of luminous spectrum and lifetime of the device. It can be seen that, on the one hand, the embodiment of the present application avoids the use of an etching process for patterning an anode layer with a large thickness. Therefore, an issue of etching residue is avoided, which is beneficial to improve product yield. On the other hand, the embodiment of the present application avoids setting a spacer between the anode layer and the reflective electrode to adjust the cavity length of the light emitting device. This simplifies manufacturing process and is beneficial to improving production efficiency, that is, to mass production.

### DESCRIPTION OF DRAWINGS

The following describes the specific implementations of the present application in detail with reference to the accompanying drawings, which will make the technical solutions and other beneficial effects of the present application obvious.

FIG. 1 is a schematic diagram of a partial cross-sectional structure of a display panel provided by an embodiment of the present application.

FIG. 2 is a schematic diagram of a partial cross-sectional structure of another display panel provided by an embodiment of the present application.

FIG. 3 is a schematic flowchart of a manufacturing method of a display panel provided by an embodiment of the present application.

FIG. 4A is a schematic diagram of a partial cross-sectional structure of an array substrate formed with reflective electrodes according to an embodiment of the present application.

FIG. 4B is a schematic diagram of a partial cross-sectional structure of an isolation unit formed on the basis of FIG. 4A.

FIG. 4C is a schematic diagram of a partial cross-sectional structure of an anode layer formed on the basis of FIG. 4B.

FIG. 4D is a schematic diagram of a partial cross-sectional structure of a pixel definition layer formed on the basis of FIG. 4C.

FIG. 4E is a schematic diagram of a partial cross-sectional structure of a light-emitting functional layer formed on the basis of FIG. 4D.

FIG. 4F is a schematic diagram of a partial cross-sectional structure of a cathode layer and an encapsulation layer formed on the basis of FIG. 4E.

### DETAILED DESCRIPTION OF PREFERRED EMBODIMENTS

The technical solutions in the embodiments of the present application will be clearly and completely described below in conjunction with the drawings in the embodiments of the present application. Obviously, the described embodiments are only a part of the embodiments of the present application, rather than all the embodiments. Based on the embodiments in the present application, all other embodiments obtained by those skilled in the art without creative work are within the protection scope of the present application.

In the description of the present application, it should be understood that orientations or positional relationships indicated by terms such as “center”, “longitudinal”, “crosswise”, “length”, “width”, “thickness”, “up”, “down”, “front”, “rear”, “left”, “right”, “vertical”, “horizontal”, “top”, “bottom”, “inside”, “outside”, “clockwise”, “anticlockwise” are orientations or positional relationships shown based on the drawings, and the terms are merely for convenience of describing the present application and for simplifying the description, but for indicating or implying that an indicated apparatus or element must have a specific orientation, and must be constructed and operated in a specific orientation, which thus may not be understood as limiting the present application. Besides, terms “first” and “second” are for a descriptive purpose only and may not be understood as indicating or implying relative importance, or implicitly indicating the quantity of indicated technical features. As such, features defined with the terms “first” and “second” may explicitly indicate or implicitly include at least one of the features. In the description of the present application, the meaning of “multiple” is two or more than two, unless explicitly and specifically defined otherwise.

In the present application, unless explicitly specified and defined otherwise, terms such as “installation”, “interconnection”, “connection” and “fixation” should be understood broadly, for example, they may either be a fixed connection, or a detachable connection, or integrated; they may either be a mechanical connection, or an electric connection; and they may either be a direct connection, or an indirect connection through an intermediary, and they may be an internal connection between two elements or an interaction relationship between the two elements, unless explicitly defined otherwise. A person of ordinary skill in the art may understand specific meanings of the above terms in the present application according to specific conditions.

In the present application, unless explicitly specified and defined otherwise, a first feature being “on” or “under” a second feature may be that the first feature and the second feature are in direct contact, or the first feature and the second feature are in indirect contact through an intermediary. In addition, the first feature being “on”, “over” and “above” the second feature may be that the first feature is just above or diagonally above the second feature, or merely represents that a horizontal height of the first feature is higher than that of the second feature. The first feature being “under”, “below” and “underneath” the second feature may be that the first feature is just below or diagonally below the second feature, or merely represents that the horizontal height of the first feature is lower than that of the second feature.

Many different implementations or examples for achieving different structures of the present application are provided hereinafter. To simplify the present application, the components and arrangements of specific examples are described below. These components and arrangements are merely exemplary and are not to be construed as a limit on the present application. In addition, the reference numerals and/or letters may be repeated in the different examples of the present application. Such repetition is for the purpose of simplification and clarity, without indicating relationships between the discussed various implementations and/or arrangements. Moreover, the present application provides examples of various specific processes and materials, but the application of other processes and/or use of other materials may also occur to persons skilled in the art.

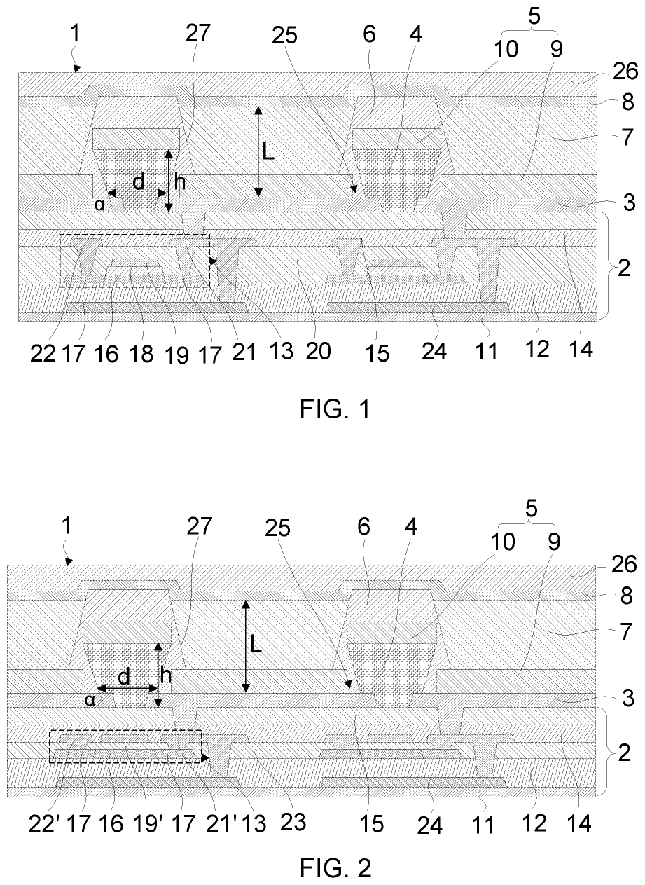

As shown in FIG. 1, an embodiment of the present application provides a top-emitting display panel 1. The display panel 1 includes an array substrate 2, a plurality of reflective electrodes 3, a plurality of isolation units 4, an anode layer 5, a pixel definition layer 6, a light-emitting functional layer 7, and a cathode layer 8. The multiple reflective electrodes 3 are located on the array substrate 2 and distributed in an array. An isolation unit 4 is provided between any two adjacent reflective electrodes 3. The anode layer 5 includes first anodes 9 on each reflective electrode 3 and second anodes 10 on a side of each isolation unit 4 away from the array substrate 2. Each first anode 9 is separated from the adjacent second anode 10 by the isolation unit 4. The light-emitting functional layer 7 is located on the first anode 9 for light-emitting display. The cathode layer 8 is located on a side of the light-emitting functional layer 7 away from the first anode 9.

Specifically, each first anode 9 and the light-emitting functional layer 7 and the cathode layer 8 arranged on the first anode 9 constitute an OLED device. A cavity length of each OLED device is a distance L between the reflective electrode 3 and the cathode layer 8.

Specifically, the array substrate 2 includes a base substrate 11, a buffer layer 12 disposed on the base substrate 11, a plurality of thin film transistors 13 disposed on the buffer layer 12 and connected to the plurality of reflective electrodes 3 in one-to-one correspondence, and a passivation layer 14 and a planarization layer 15 disposed on the plurality of thin film transistors 13. Each thin film transistor 13 includes a semiconductor unit 16 (i.e., a channel layer) disposed on the buffer layer 12, a doping unit 17 (i.e., an ohmic contact layer) disposed on the buffer layer 12 and located on both sides of the semiconductor unit 16, a gate insulating unit 18 disposed on the semiconductor unit 16, a gate 19 disposed on the gate insulating unit 18, an interlayer insulating layer 20 covering the buffer layer 12, the doping unit 17, the gate insulating unit 18, and the gate 19, and a source 21 and a drain 22 disposed on the interlayer insulating layer 20. The source 21 and the drain 22 are respectively connected to the doped unit 17 on both sides of the semiconductor unit 16 through two continuous through holes penetrating the interlayer insulating layer 20. As shown in FIG. 2, in another embodiment, the gate 19′, the source 21′, and the drain 22′ are arranged in the same layer, which can save an interlayer insulating layer. Specifically, each thin film transistor 13 includes a semiconductor unit 16 (that is, a channel layer) disposed on the buffer layer 12, a doping unit 17 (that is, an ohmic contact unit) disposed on the buffer layer 12 and located on both sides of the semiconductor unit 16, a gate insulating layer 23 arranged on the buffer layer 12, the semiconductor unit 16 and the doped unit 17, a gate 19′, a source 21′, and a drain 22′ arranged on the gate insulating layer 23 and spaced apart from each other. The source 21′ and the drain 22′ are respectively located on both sides of the gate 19′. The gate 19′ is provided corresponding to the semiconductor unit 16. The source 21′ and the drain 22′ are respectively connected to the doping unit 17 on both sides of the semiconductor unit 16 through two continuous through holes penetrating the interlayer insulating layer 20.

It should be noted that the present application does not limit the specific type and structure of the thin film transistor 13 in the array substrate 2, and the embodiment of the present application takes the structure of the thin film transistor 13 shown in FIG. 1 as an example.

As shown in FIG. 1, the array substrate 2 further includes a plurality of light shielding (LS) units 24 arranged between the base substrate 11 and the buffer layer 12 and arranged in one-to-one correspondence with the plurality of thin film transistors 13. Specifically, an orthographic projection of each light shielding unit 24 on the base substrate 11 completely covers an orthographic projection of the semiconductor unit 16 in the corresponding thin film transistor 13 and the doping unit 17 located on both sides of the semiconductor unit 16 on the base substrate 11. The light shielding unit 24 is used to protect a channel layer of the thin film transistor 13 from being affected by light, and to avoid phenomenon of light-induced leakage current. In another embodiment, the light shielding unit 24 is further extended to correspond to the source 21 and is connected to the source 21 through a through hole penetrating the buffer layer 12 and the interlayer insulating layer 20 (or the gate insulating layer 23).

Specifically, the material of the semiconductor unit 16 includes IGZO (indium gallium zinc oxide). Of course, the material of the semiconductor unit 16 is not limited here.

Specifically, the array substrate 2 includes a display area for displaying images and a non-display area located at a periphery of the display area (only part of the structure in the display area is shown in the figure). A plurality of thin film transistors 13 are located in the display area. Correspondingly, a plurality of reflective electrodes 3 and anode layers 5 are all located in the display area.

Specifically, the material of the reflective electrode 3 includes metals or alloys such as Ag, Al, etc., and is used to reflect the light emitted by the light-emitting functional layer 7 in a direction away from the array substrate 2 to achieve top emission. Each reflective electrode 3 is connected to the source 21 of the corresponding thin film transistor 13 through a through hole penetrating the planarization layer 15 and the passivation layer 14. It should be noted that in this embodiment, the source 21 and the drain 22 of each thin film transistor 13 can be interchanged. For example, in one embodiment, each reflective electrode 3 is connected to the drain of the corresponding thin film transistor 13 through a through hole penetrating the planarization layer 15 and the passivation layer 14.

Specifically, the material of the isolation unit 4 is an electrically insulating material. A width d of the isolation unit 4 gradually increases in a direction of the array substrate 2 toward the second anode 10. An orthographic projection of an upper surface of the isolation unit 4 on the array substrate 2 completely covers an orthographic projection of a lower surface of the isolation unit 4 on the array substrate 2. It should be noted that the upper surface of the isolation unit 4 refers to a surface of the isolation unit 4 away from a side of the array substrate 2. The lower surface of the isolation unit 4 refers to a surface of the isolation unit 4 close to a side of the array substrate 2. A thickness h of the isolation unit 4 is greater than a sum of thicknesses of the reflective electrode 3 and the first anode 9. In an embodiment, a shape of a cross section of the isolation unit 4 in a direction perpendicular to the array substrate 2 is an inverted trapezoid. The cross section includes two oblique sides arranged oppositely. An angle between each oblique side and the upper surface of the array substrate 2 is α, where the angle α is less than or equal to 60°. The smaller the angle α is, the better the isolation effect of the isolation unit 4 on the anode layer 5 is. In one embodiment, in order to ensure stability of the structure of the isolation unit 4, the angle α is greater than or equal to 45° and less than or equal to 60°.

Since the isolation unit 4 has an inverted trapezoid or similar inverted trapezoid structure, and a thickness h of the isolation unit 4 is greater than a sum of thicknesses of the reflective electrode 3 and the first anode 9. This makes the angle between the side surface of the isolation unit 4 and the upper surface of the reflective electrode 3 an acute angle. There is a gap between the isolation unit 4 and the reflective electrode 3 having a height greater than the thickness of the anode layer 5. When the anode layer 5 is formed by evaporation or sputtering on the entire display area of the array substrate 2 on which the reflective electrode 3 and the isolation unit 4 are formed, the angle between the side surface of the isolation unit 4 and the upper surface of the reflective electrode 3 is an acute angle, which avoids the formation of an anode layer on the side surface of the isolation unit 4. Therefore, it is avoided that the first anode 9 on the reflective electrode 3 and the second anode 10 on the side of the isolation unit 4 away from the array substrate 2 are connected through the side surface of the isolation unit 4. The gap between the isolation unit 4 and the reflective electrode 3 causes a distance between the first anode 9 and the second anode 10 in a direction perpendicular to the array substrate 2. It is further avoided that the first anode 9 on the reflective electrode 3 is connected to the second anode 10 on the side of the isolation unit 4 away from the array substrate 2. Therefore, the isolation unit 4 in the embodiment of the present application can naturally disconnect the anode layer 5 into a plurality of first anodes 9 and second anodes 10 that are not connected to each other.

Specifically, the material of the anode layer 5 includes indium tin oxide (ITO). The first anode 9 and the second anode 10 have the same material and the same thickness. The first anode 9 is the anode electrode of the light-emitting functional layer 7. It can be understood that the orthographic projections of any one of the first anode 9 and the adjacent second anode 10 on the array substrate 2 are connected or partially overlapped. Through the isolation unit 4, any two adjacent first anodes 9 are also naturally spaced apart. Therefore, the patterning of the anode layer 5 does not require an etching process, which avoids issues of etching residue and etching difficulties.

In one embodiment, the thickness of the first anode 9 is greater than or equal to 800 A (Angstroms). The thickness h of the isolation unit 4 is greater than or equal to 1 um (micrometer). In this embodiment, the cavity length of the OLED device can be adjusted by the thickness of the first anode 9 to improve the luminous efficiency, the precision of the luminous spectrum, and the lifetime of the device. In other words, the thickness of the first anode 9 can be adjusted according to the cavity length requirements of the OLED device. This avoids setting a spacer between the anode layer 5 and the reflective electrode 3 to adjust the cavity length of the light emitting device.

In an embodiment, the bottom of the isolation unit 4 is located on the planarization layer 15 exposed by two adjacent reflective electrodes 3. The isolation unit 4 partially covers two adjacent reflective electrodes 3. The first anode 9 is located on the corresponding reflective electrode 3 and is not connected (not in contact) with the adjacent isolation unit 4. Since the bottom width of the isolation unit 4 is smaller than the top width, an undercut opening 25 is formed between each isolation unit 4 and the adjacent first anode 9 and the reflective electrode 3.

Specifically, the pixel definition layer 6 covers the upper surface and the side surface of each second anode 10 and partially covers the first anode 9 and the reflective electrode 3 to form a pixel opening 27. The light-emitting functional layer 7 is located in the pixel opening 27. It can be understood that the pixel definition layer 6 is also filled in each undercut opening 25. In other words, the pixel definition layer 6 wraps around the outer surface of the second anode 10 and the isolation unit 4, and partially covers the edges of the first anode 9 and the reflective electrode 3. This makes the pixel definition layer 6 enclose a pixel opening 27 on the first anode 9. The pixel definition layer 6 is wrapped on the outer surface of the second anode 10 to prevent the conductive second anode 10 from electrically connecting two adjacent light-emitting functional layers 7. Therefore, it is ensured that the display panel 1 can display normally, and the service life of the device is improved.

In an embodiment, the material of the pixel definition layer 6 and the isolation unit 4 may be the same. Of course, the present application does not limit this.

Specifically, the light-emitting functional layer 7 includes a hole injection layer, a hole transport layer, a light-emitting layer, an electron transport layer, and an electron injection layer sequentially disposed on each first anode 9. The light-emitting functional layer 7 can be made of organic ink materials or vapor-deposited organic materials. Correspondingly, it can be formed by inkjet printing technology, or can be formed by vapor deposition technology. When the light-emitting functional layer 7 in the display panel 1 is formed by inkjet printing technology, the material of the pixel definition layer 6 is a hydrophobic material. When the light-emitting functional layer 7 in the display panel 1 is formed by evaporation technology, the material of the pixel definition layer 6 may be a non-hydrophobic material.

In an embodiment, the display panel 1 may be an RGB-OLED display panel. That is to say, light-emitting layers in different light-emitting functional layers 7 can respectively emit red light, green light, and blue light to achieve full-color display. In another embodiment, the display panel 1 may be a W-OLED display panel. That is, all the light-emitting layers in the light-emitting functional layer 7 emit white light. The display panel 1 also includes a color filter corresponding to each OLED device to realize full-color display.

Specifically, the cathode layer 8 can be laid as a whole layer to reduce process difficulty. This application does not limit the specific structure of the cathode layer 8.

Specifically, the display panel 1 further includes an encapsulation layer 26 on the cathode layer 8 to prevent external water and oxygen from entering the OLED device and can protect the OLED device.

In this embodiment, the isolation unit 4 is provided between any two adjacent reflective electrodes 3. This makes it possible to form the first anodes 9 on the reflective electrode 3 and the second anodes 10 on the isolation unit 4 when the anode layer 5 is formed on the array substrate 2 on which the isolation unit and the reflective electrodes 3 are formed. The first anode 9 and the second anode 10 are naturally separated by an isolation unit. Therefore, any two adjacent first anodes 9 are naturally separated by the isolation unit 4. Therefore, in the present application, the first anodes 9 with a large thickness and spaced apart can be directly formed without using an etching process when making the anode layer 5. This is beneficial to adjust the cavity length of the OLED device in the display panel 1 through the thickness of the first anode 9 to improve the luminous efficiency, the precision of the luminous spectrum, and the lifetime of the device. It can be seen that, on the one hand, the embodiment of the present application avoids the use of an etching process for patterning the anode layer 5 with a large thickness. Therefore, an issue of etching residue is avoided, which is beneficial to improve the product yield. On the other hand, the embodiment of the present application avoids setting a spacer between the anode layer 5 and the reflective electrode 3 to adjust the cavity length of the light emitting device. This simplifies the manufacturing process and is beneficial to improving production efficiency, that is, to mass production.

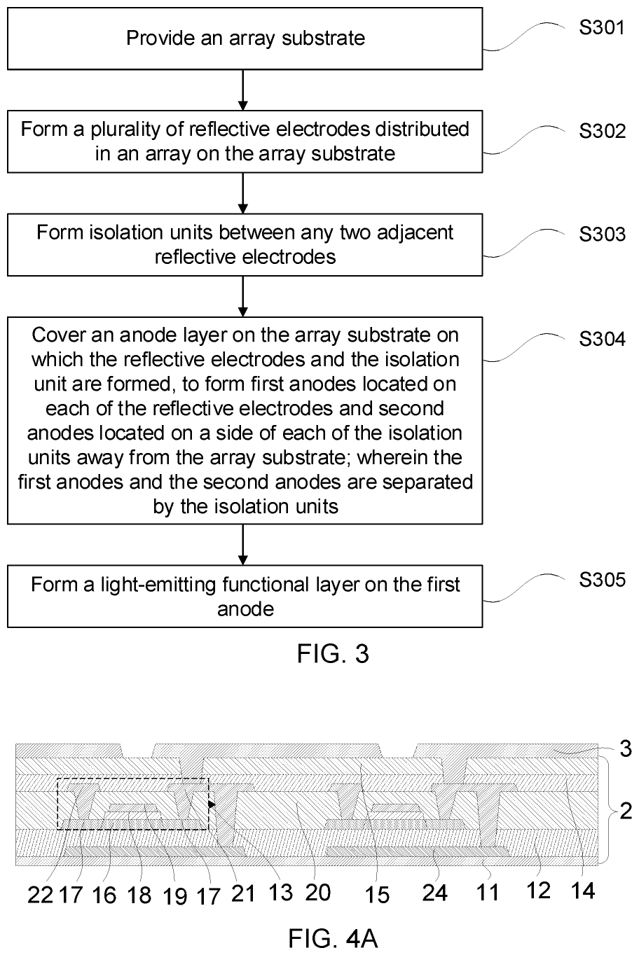

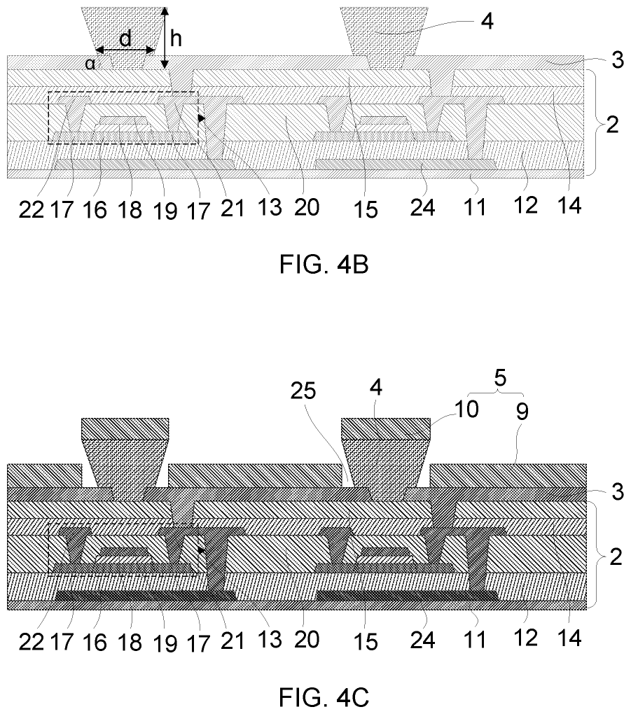

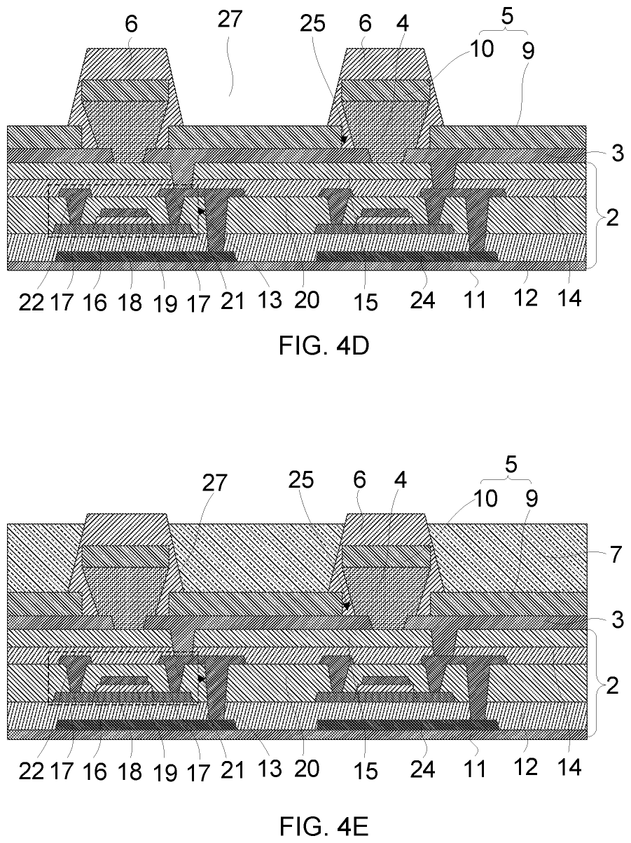

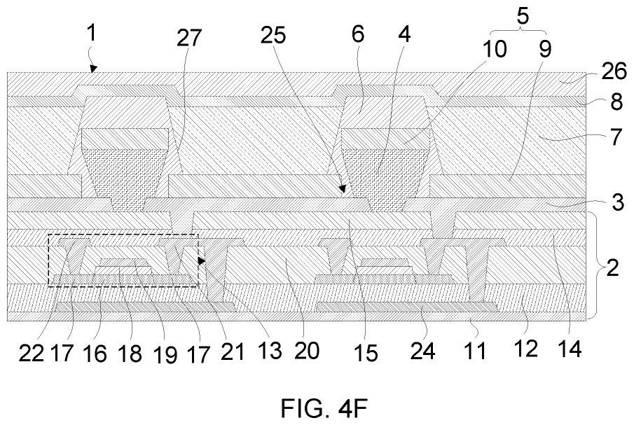

As shown in FIG. 3 and FIG. 4A to FIG. 4F, an embodiment of the present application also provides a manufacturing method of the display panel 1, including steps S301 to S305.

Step S301: Provide an array substrate.

Specifically, as shown in FIG. 4A, the array substrate 2 includes a base substrate 11, a buffer layer 12 disposed on the base substrate 11, a plurality of thin film transistors 13 disposed on the buffer layer 12, and a passivation layer 14 and a planarization layer 15 disposed on the plurality of thin film transistors 13. Each thin film transistor 13 includes a semiconductor unit 16 (i.e., a channel layer) disposed on the buffer layer 12, a doping unit 17 (i.e., an ohmic contact layer) disposed on the buffer layer 12 and located on both sides of the semiconductor unit 16, a gate insulating unit 18 disposed on the semiconductor unit 16, a gate 19 disposed on the gate insulating unit 18, an interlayer insulating layer 20 covering the buffer layer 12, the doping unit 17, the gate insulating unit 18, and the gate 19, and a source 21 and a drain 22 disposed on the interlayer insulating layer 20. The source 21 and the drain 22 are respectively connected to the doped unit 17 on both sides of the semiconductor unit 16 through two continuous through holes penetrating the interlayer insulating layer 20.

In another embodiment, the gate, the source, and the drain are arranged in the same layer, which can save an interlayer insulating layer. Specifically, each thin film transistor includes a semiconductor unit (that is, a channel layer) disposed on the buffer layer, a doping unit (that is, an ohmic contact unit) disposed on the buffer layer and located on both sides of the semiconductor unit, a gate insulating layer arranged on the buffer layer, the semiconductor unit and the doped unit, a gate, a source, and a drain arranged on the gate insulating layer and spaced apart from each other. The source and the drain are respectively located on both sides of the gate. The gate is provided corresponding to the semiconductor unit. The source and the drain are respectively connected to the doping unit on both sides of the semiconductor unit through two continuous through holes penetrating the interlayer insulating layer.

Specifically, as shown in FIG. 4A, the array substrate 2 further includes a plurality of light shielding units 24 arranged between the base substrate 11 and the buffer layer 12 and arranged in one-to-one correspondence with the plurality of thin film transistors 13. Specifically, an orthographic projection of each light shielding unit 24 on the base substrate 11 completely covers an orthographic projection of the semiconductor unit 16 in the corresponding thin film transistor 13 and the doping unit 17 located on both sides of the semiconductor unit 16 on the base substrate 11. The light shielding unit 24 is used to protect the channel layer of the thin film transistor 13 from being affected by light, and to avoid phenomenon of light-induced leakage current. In another embodiment, the light shielding unit 24 is also extended to correspond to the source 21 and is connected to the source 21 through a through hole penetrating the buffer layer 12 and the interlayer insulating layer 20.

Specifically, the material of the semiconductor unit 16 includes IGZO (indium gallium zinc oxide). Of course, the material of the semiconductor unit 16 is not limited here.

Step S302: Form a plurality of reflective electrodes distributed in an array on the array substrate.

Specifically, step S302 includes the following steps.

Use PVD (physical vapor deposition) process to deposit a reflective film on the array substrate.

A reflective film is patterned using a photoetching process to form a plurality of reflective electrodes distributed in an array.

Specifically, as shown in FIG. 4A, the multiple reflective electrodes 3 are connected to the multiple thin film transistors 13 in the array substrate 2 in one-to-one correspondence. Each reflective electrode 3 is connected to the source 21 of the corresponding thin film transistor 13 through a through hole penetrating the planarization layer 15 and the passivation layer 14. It should be noted that in this embodiment, the source 21 and the drain 22 of each thin film transistor 13 can be interchanged. For example, in one embodiment, each reflective electrode 3 is connected to the drain of the corresponding thin film transistor 13 through a through hole penetrating the planarization layer 15 and the passivation layer 14.

Specifically, the material of the reflective electrode 3 includes metals or alloys such as Ag, Al, etc., and is used to reflect the light emitted by the light-emitting functional layer 7 in a direction away from the array substrate 2 to achieve top emission.

Step S303: Form isolation units between any two adjacent reflective electrodes.

Specifically, the material of the isolation unit is an electrically insulating material. As shown in FIG. 4B, a width d of the isolation unit 4 gradually increases in a direction of the array substrate 2 toward the reflective electrode 3. An orthographic projection of an upper surface of the isolation unit 4 on the array substrate 2 completely covers an orthographic projection of a lower surface of the isolation unit 4 on the array substrate 2. It should be noted that the upper surface of the isolation unit 4 refers to a surface of the isolation unit 4 away from a side of the array substrate 2. The lower surface of the isolation unit 4 refers to a surface of the isolation unit 4 close to a side of the array substrate 2. In an embodiment, a shape of a cross section of the isolation unit 4 in a direction perpendicular to the array substrate 2 is an inverted trapezoid. The cross section includes two oblique sides arranged oppositely. An angle between each oblique side and the upper surface of the array substrate 2 is α, where the angle α is less than or equal to 60°. The smaller the angle α is, the better the isolation effect of the isolation unit 4 on the anode layer 5 is. In one embodiment, in order to ensure stability of the structure of the isolation unit 4, the angle α is greater than or equal to 45° and less than or equal to 60°.

Specifically, the bottom of the isolation unit 4 is located on the planarization layer 15 exposed by two adjacent reflective electrodes 3, and the isolation unit 4 partially covers the two adjacent reflective electrodes 3.

Step S304: Cover an anode layer on the array substrate on which the reflective electrodes and the isolation unit are formed, to form first anodes located on each of the reflective electrodes and second anodes located on a side of each of the isolation units away from the array substrate; wherein the first anodes and the second anodes are separated by the isolation units.

Specifically, as shown in FIG. 4C, the anode layer 5 includes first anodes 9 on each reflective electrode 3 and second anodes 10 on a side of each isolation unit 4 away from the array substrate 2. The material of the anode layer 5 includes indium tin oxide (ITO). The anode layer 5 can be formed by an evaporation process or a sputtering process. It should be noted that when the anode layer 5 is formed by an evaporation process, the anode layer 5 is disconnected at the isolation unit 4 to form the first anode 9 and the second anode 10 more effectively.

In order to ensure the isolation effect of the first anode 9 and the second anode 10, a thickness h of the isolation unit 4 is greater than a sum of thicknesses of the reflective electrode 3 and the first anode 9. Since the isolation unit 4 has an inverted trapezoid or similar inverted trapezoid structure, and a thickness h of the isolation unit 4 is greater than a sum of thicknesses of the reflective electrode 3 and the first anode 9. This makes the angle between the side surface of the isolation unit 4 and the upper surface of the reflective electrode 3 an acute angle. There is a gap between the isolation unit 4 and the reflective electrode 3 having a height greater than the thickness of the anode layer 5. When the anode layer 5 is formed by evaporation or sputtering on the entire display area of the array substrate 2 on which the reflective electrode 3 and the isolation unit 4 are formed, the angle between the side surface of the isolation unit 4 and the upper surface of the reflective electrode 3 is an acute angle, which avoids the formation of an anode layer on the side surface of the isolation unit 4. Therefore, it is avoided that the first anode 9 on the reflective electrode 3 and the second anode 10 on the side of the isolation unit 4 away from the array substrate 2 are connected through the side surface of the isolation unit 4. The gap between the isolation unit 4 and the reflective electrode 3 causes a distance between the first anode 9 and the second anode 10 in a direction perpendicular to the array substrate 2. It is further avoided that the first anode 9 on the reflective electrode 3 is connected to the second anode 10 on the side of the isolation unit 4 away from the array substrate 2. Therefore, the isolation unit 4 in the embodiment of the present application can naturally disconnect the anode layer 5 into a plurality of first anodes 9 and second anodes 10 that are not connected to each other.

Specifically, the first anode 9 and the second anode 10 have the same material and the same thickness. The first anode 9 is the anode electrode of the light-emitting functional layer 7. It can be understood that the orthographic projections of any one of the first anode 9 and the adjacent second anode 10 on the array substrate 2 are connected or partially overlapped. Through the isolation unit 4, any two adjacent first anodes 9 are also naturally spaced apart. Therefore, the patterning of the anode layer 5 does not require an etching process, which avoids issues of etching residue and etching difficulties.

In one embodiment, the thickness of the first anode 9 is greater than or equal to 800 A (Angstroms). The thickness h of the isolation unit 4 is greater than or equal to 1 um (micrometer). In this embodiment, the cavity length of the OLED device can be adjusted by the thickness of the first anode 9 to improve the luminous efficiency, the precision of the luminous spectrum, and the lifetime of the device. In other words, the thickness of the first anode 9 can be adjusted according to the cavity length requirements of the OLED device. This avoids setting a spacer between the anode layer 5 and the reflective electrode 3 to adjust the cavity length of the light emitting device.

In an embodiment, the first anode 9 is located on the corresponding reflective electrode 3 and is not connected (not in contact) with the adjacent isolation unit 4. Since the bottom width of the isolation unit 4 is smaller than the top width, an undercut opening 25 is formed between each isolation unit 4 and the adjacent first anode 9 and the reflective electrode 3.

Specifically, the array substrate 2 includes a display area for displaying images and a non-display area located at a periphery of the display area (only part of the structure in the display area is shown in the figure). When the anode layer 5 is formed, the non-display area can be shielded to prevent the anode layer 5 from being formed in the non-display area. This causes shorting of the metal layer in the non-display area, etc. The area of the non-display area is relatively large, and the shielding of the non-display area will not affect an aperture ratio of the display panel 1.

Step S305: Form a light-emitting functional layer on the first anode.

Specifically, step S305 includes the following steps.

As shown in FIG. 4D, a pixel definition layer 6 covering the upper and side surfaces of each second anode 10 is formed. The pixel definition layer 6 also partially covers the first anode 9 and the reflective electrode 3 to form a pixel opening 27.

As shown in FIG. 4E, a light-emitting functional layer 7 is formed on the first anode 9 located in the pixel opening 27.

Specifically, the pixel definition layer 6 is also filled in each undercut opening 25. In other words, the pixel definition layer 6 wraps around the outer surface of the second anode 10 and the isolation unit 4, and partially covers the edges of the first anode 9 and the reflective electrode 3. This makes the pixel definition layer 6 enclose a pixel opening 27 on the first anode 9. The pixel definition layer 6 is wrapped on the outer surface of the second anode 10 to prevent the conductive second anode 10 from electrically connecting two adjacent light-emitting functional layers 7. Therefore, it is ensured that the display panel 1 can display normally, and the service life of the device is improved.

Specifically, the light-emitting functional layer 7 includes a hole injection layer, a hole transport layer, a light-emitting layer, an electron transport layer, and an electron injection layer sequentially disposed on each first anode 9. The light-emitting functional layer 7 can be made of organic ink materials or vapor-deposited organic materials. Correspondingly, it can be formed by inkjet printing technology, or can be formed by vapor deposition technology. When the light-emitting functional layer 7 in the display panel 1 is formed by inkjet printing technology, the material of the pixel definition layer 6 is a hydrophobic material. When the light-emitting functional layer 7 in the display panel 1 is formed by evaporation technology, the material of the pixel definition layer 6 may be a non-hydrophobic material.

In an embodiment, the display panel 1 may be an RGB-OLED display panel. That is to say, light-emitting layers in different light-emitting functional layers 7 can respectively emit red light, green light, and blue light to achieve full-color display. In another embodiment, the display panel 1 may be a W-OLED display panel. That is, all the light-emitting layers in the light-emitting functional layer 7 emit white light. The display panel 1 also includes a color filter corresponding to each OLED device to realize full-color display.

As shown in FIG. 4F, the manufacturing method of the display panel 1 further includes the following steps.

A cathode layer 8 is formed on the array substrate 2 on which the pixel definition layer 6 and the light-emitting functional layer 7 are formed.

An encapsulation layer 26 is formed on the cathode layer 8.

Specifically, the cathode layer 8 can be laid as a whole layer to reduce process difficulty. Each first anode 9 and the light-emitting functional layer 7 and the cathode layer 8 arranged on the first anode 9 constitute an OLED device. The cavity length of each OLED device is the distance L between the reflective electrode 3 and the cathode layer 8. The encapsulation layer 26 can prevent external water and oxygen from entering the OLED device and can protect the OLED device.

In this embodiment, the isolation unit 4 is provided between any two adjacent reflective electrodes 3. This makes it possible to form the first anodes 9 on the reflective electrode 3 and the second anodes 10 on the isolation unit 4 when the anode layer 5 is formed on the array substrate 2 on which the isolation unit and the reflective electrodes 3 are formed. The first anode 9 and the second anode 10 are naturally separated by an isolation unit. Therefore, any two adjacent first anodes 9 are naturally separated by the isolation unit 4. Therefore, in the present application, the first anodes 9 with a large thickness and spaced apart can be directly formed without using an etching process when making the anode layer 5. This is beneficial to adjust the cavity length of the OLED device in the display panel 1 through the thickness of the first anode 9 to improve the luminous efficiency, the precision of the luminous spectrum, and the lifetime of the device. It can be seen that, on the one hand, the embodiment of the present application avoids the use of an etching process for patterning the anode layer 5 with a large thickness. Therefore, an issue of etching residue is avoided, which is beneficial to improve the product yield. On the other hand, the embodiment of the present application avoids setting a spacer between the anode layer 5 and the reflective electrode 3 to adjust the cavity length of the light emitting device. This simplifies the manufacturing process and is beneficial to improving production efficiency, that is, to mass production.

In the above-mentioned embodiments, the description of each embodiment has its own focus. For parts that are not described in detail in an embodiment, reference may be made to related descriptions of other embodiments.

The foregoing describes in detail a display panel and a manufacturing method of the same provided by the embodiments of the present application. Specific examples are used in this article to illustrate the principle and implementation of the present application. The descriptions of the above embodiments are only used to help understand the technical solutions and core ideas of this application. Those of ordinary skill in the art should understand that they can still modify the technical solutions recorded in the foregoing embodiments, or equivalently replace some of the technical features. However, these modifications or replacements do not cause the essence of the corresponding technical solutions to deviate from the scope of the technical solutions of the embodiments of the present application.

What is claimed is:

1. A display panel, comprising:
an array substrate;
a plurality of reflective electrodes located on the array substrate and distributed in an array;
a plurality of isolation units, wherein one isolation unit is arranged between any two adjacent reflective electrodes;
an anode layer comprising first anodes located on each of the reflective electrodes and second anodes located on a side of each of the isolation units away from the array substrate;
a light-emitting functional layer located on the first anode;
wherein each of the first anodes is separated from the adjacent second anodes by the isolation unit.

2. The display panel according to claim 1, wherein a width of the isolation unit gradually increases in a direction of the array substrate toward the second anode, and an orthographic projection of an upper surface of the isolation unit on the array substrate completely covers an orthographic projection of a lower surface of the isolation unit on the array substrate.

3. The display panel according to claim 2, wherein a shape of a cross section of the isolation unit in a direction perpendicular to the array substrate is an inverted trapezoid.

4. The display panel according to claim 3, wherein the cross section comprises two oppositely arranged oblique sides; an angle between each oblique side and an upper surface of the array substrate is greater than or equal to 45° and less than or equal to 60°.

5. The display panel according to claim 1, wherein a thickness of the isolation unit is greater than a sum of thicknesses of the reflective electrode and the first anode.

6. The display panel according to claim 5, wherein the thickness of the first anode is greater than or equal to 800 A; the thickness of the isolation unit is greater than or equal to 1 um.

7. The display panel according to claim 1, further comprising a pixel definition layer covering an upper surface and a side surface of each of the second anodes.

8. The display panel according to claim 7, wherein the pixel definition layer further partially covers the first anode and the reflective electrode to form a pixel opening, and the light-emitting functional layer is located in the pixel opening.

9. The display panel according to claim 1, wherein material of the anode layer comprises indium tin oxide.

10. The display panel according to claim 1, wherein the first anode and the second anode have same material and a same thickness.

11. The display panel according to claim 1, wherein the array substrate comprises a base substrate, a buffer layer disposed on the base substrate, and a plurality of thin film transistors disposed on the buffer layer and connected to the plurality of reflective electrodes in a one-to-one correspondence.

12. A manufacturing method of a display panel, comprising following steps:
providing an array substrate;
forming a plurality of reflective electrodes distributed in an array on the array substrate;
forming isolation units between any two adjacent reflective electrodes;
covering an anode layer on the array substrate on which the reflective electrodes and the isolation unit are formed, to form first anodes located on each of the reflective electrodes and second anodes located on a side of each of the isolation units away from the array substrate; wherein the first anodes and the second anodes are separated by the isolation units; and
forming a light-emitting functional layer on the first anode.

13. The manufacturing method of the display panel according to claim 12, wherein a width of the isolation unit gradually increases in a direction of the array substrate toward the second anode, and an orthographic projection of an upper surface of the isolation unit on the array substrate completely covers an orthographic projection of a lower surface of the isolation unit on the array substrate.

14. The manufacturing method of the display panel according to claim 13, wherein a shape of a cross section of the isolation unit in a direction perpendicular to the array substrate is an inverted trapezoid.

15. The manufacturing method of the display panel according to claim 14, wherein the cross section comprises two oppositely arranged oblique sides; an angle between each oblique side and an upper surface of the array substrate is greater than or equal to 45° and less than or equal to 60°.

16. The manufacturing method of the display panel according to claim 12, wherein a thickness of the isolation unit is greater than a sum of thicknesses of the reflective electrode and the first anode.

17. The manufacturing method of the display panel according to claim 16, wherein the thickness of the first anode is greater than or equal to 800 A; the thickness of the isolation unit is greater than or equal to 1 um.

18. The manufacturing method of the display panel according to claim 12, wherein forming the light-emitting functional layer on the first anode comprises following steps:
forming a pixel definition layer covering an upper surface and a side surface of each of the second anodes, wherein the pixel definition layer further partially covers the first anode and the reflective electrode to form a pixel opening;
forming the light-emitting functional layer on the first anode located in the pixel opening.

19. The manufacturing method of the display panel according to claim 12, wherein material of the anode layer comprises indium tin oxide.

20. The manufacturing method of the display panel according to claim 12, wherein the first anode and the second anode have same material and a same thickness.
